(19) United States
(12) Patent Application Publication
(10) Pub. No.: US 2026/0143608 A1
(43) Pub. Date: May 21, 2026

(54) SUBSTRATE, POWER MODULE, ELECTRICAL DEVICE AND METHOD FOR PRODUCING A POWER MODULE

(71) Applicant: SIEMENS AKTIENGESELLSCHAFT, München (DE)

(72) Inventors: Matthias NÄHRIG, Erlangen (DE); Felix ZEYSS, Erlangen (DE)

(21) Appl. No.: 19/116,927

(22) PCT Filed: Jun. 28, 2023
(86) PCT No.: PCT/EP2023/067655

§ 371 Date: Mar. 28, 2025

(30) Foreign Application Priority Data
Sep. 28, 2022 (EP) 22198412

(51) Int. Cl. H05K 5/02; H05K 5/00; H05K 7/14

(52) U.S. Cl. CPC H05K 5/0247; H05K 5/0069; H05K 7/1432

(57) ABSTRACT

The invention relates, inter alia, to a substrate (1) for a power module, wherein the substrate (1) is designed, in a plan view, substantially rectangularly with two opposite long sides (2A, 2B) and two opposite short sides (3A, 3B), and wherein the substrate (1) has a plurality of semiconductors (4) for converting a three-phase alternating voltage (AC) into a positive, a medium and a negative direct voltage (DC) or to convert a positive, a medium and a negative direct voltage (DC) into a three-phase alternating voltage (AC). In particular to provide an improved substrate, the invention proposes that the substrate further has: —three AC connections (AC1, AC2, AC3) arranged on the long sides (2A, 2B), —one positive DC connection (DCP) arranged on the first short side (3A), —one first medium DC connection (DCM1) arranged on the first short side (3A) —one second medium DC connection (DCM2) arranged on the second short side (3B) and —one negative DC connection (DCN) arranged on the second short side (3B), wherein the positive DC connection (DCP) is arranged closer to the first long side (2A) than the first medium DC connection (DCM1), and wherein the negative DC connection (DCN) is arranged closer to the second long side (2B) than the second medium DC connection (DCM2).

This application is the National Stage of International Application No. PCT/EP2023/067655, filed Jun. 28, 2023, which claims the benefit of European Patent Application No. EP 22198412, filed Sep. 28, 2022. The entire contents of these documents are hereby incorporated herein by reference.

### BACKGROUND

The present embodiments relate to a substrate for a power module, a power module have at least one such substrate, an electrical device (e.g., a converter) having at least one such power module, and a method for producing such a power module.

Power modules and methods for producing power modules are used in a variety of applications in power electronics. For example, in multi-phase semiconductor modules with a half-bridge topology, intermediate circuit connections are led out symmetrically on both sides in order to achieve a most uniform inductance possible for the individual phases. This is also desirable in a 3-level topology and therefore requires additional space. With small housing sizes, this is difficult to achieve due to the limited space for connections while maintaining the clearance and creepage distances. Alternatively, other housing types may be selected that provide more space.

A power semiconductor module with four power connections is known from U.S. Pat. No. 8,847,328B1. An insulated-gate bipolar transistor (IGBT) has a collector connected to the first power connection and an emitter coupled to the third power connection. An anti-parallel diode is coupled in parallel to the IGBT. A DC link is connected between the second and fourth power connections. The DC link may include two diodes and two IGBTs, where the IGBTs are connected in a common collector configuration. The first and second power connections are arranged in a first line along one side of the module, and the third and fourth power connections are arranged in a second line along the opposite side of the module. Two same instances of the module may be connected together to form a three-stage NPC phase leg with low leakage inductances, where the phase leg has two parallel DC connections.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, an improved substrate, a corresponding power module, a corresponding electrical device, and a corresponding method for producing a power module are provided.

In one embodiment, an arrangement of AC connections and DC connections is configured such that a comparatively even distribution of inductances among the three alternating voltage phases in the substrate takes place, and the comparatively even distribution of the impedances is also achieved by the impedances of the individual alternating voltage phases being configured comparatively symmetrically thanks to the arrangement of the DC connections.

In another embodiment, a power module includes a substrate and a module housing that at least partially encloses the substrate.

In another embodiment, an electrical device is provided in that an arrangement of the AC connections and the DC connections is configured such that a comparatively even distribution of the inductances among the three alternating voltage phases in the substrate takes place and the comparatively even distribution of the impedances is also achieved by the impedances of the individual alternating voltage phases being configured comparatively symmetrically thanks to the arrangement of the DC connections.

In another embodiment, a method for producing the proposed power module is provided. The method includes the following method acts: Providing an output power module having at least two output power module voltage connections arranged on the first short side, at least two output power module voltage connections arranged on the second short side, and an output module housing for accommodating and for at least partially enclosing the substrate-. The method also includes inserting the substrate into the output power module and establishing a respective electrical connection from the four DC connections of the substrate to the four output power module voltage connections. The arrangement of the AC connections and the DC connections is configured such that a comparatively even distribution of the inductances among the three alternating voltage phases in the substrate takes place and the comparatively even distribution of the impedances is also achieved by the impedances of the individual alternating voltage phases being configured comparatively symmetrically thanks to the arrangement of the DC connections.

The substrate of the present embodiments may be, for example, a direct copper bonded (DCB) substrate or an active metal brazing (AMB) substrate. In some examples, a printed circuit board (PCB) may also be used as a substrate. Further, the substrate may also be configured in two pieces or in several pieces.

In a plan view, the substrate is configured substantially rectangularly, where the substrate may be configured as a flat plate or a flat cuboid. If the substrate is configured in two pieces or in several pieces, the substrate formed from the two or more substrate pieces has a substantially rectangular outline in a plan view.

To convert the three-phase alternating voltage into three different direct voltages or vice versa, the substrate has a plurality of semiconductors, such as transistors, which are configured as power MOSFETs, IGBTs, etc., for example, or diodes. The semiconductors may be power semiconductors and are also suitable (e.g., according to a 3-stage design, interconnected and electrically connected to the AC connections and the DC connections).

The three AC connections for the three phases of the alternating voltage are arranged on the long sides of the substantially rectangular substrate. Four DC connections are provided for the three different direct voltages (e.g., a positive DC connection for a positive direct voltage, two middle DC connections for a medium or neutral direct voltage, and a negative DC connection for a negative direct voltage). The four DC connections are arranged on the short sides of the substantially rectangular substrate as follows. The positive DC connection and the first middle DC connection are arranged on the first short side of the substantially rectangular substrate. The positive DC connection is arranged closer to the first long side of the substantially rectangular substrate than the first middle DC connection. The second middle DC connection and the negative DC connection are arranged on the second short side of the substantially rectangular substrate. The negative DC connection is arranged closer to the second long side of the substantially rectangular substrate than the second middle DC connection.

For illustration purposes, let us assume that the substrate is viewed in a plan view and the substrate is aligned such that the long sides are arranged at the top and bottom, and the short sides of the substrate are arranged at the left and right. The AC connections are then arranged at the top and/or bottom, the positive DC connection is arranged at the top left, the first middle DC connection is arranged at the bottom left, the second middle DC connection is arranged at the top right, and the negative DC connection is arranged at the bottom right.

The explained configuration of the substrate (e.g., the special arrangement of the AC connections and the DC connections) brings about a comparatively even distribution of the impedances and/or inductances (e.g., among the three alternating voltage phases in the substrate). The comparatively even distribution of the impedances is achieved, for example, by the impedances of the individual alternating voltage phases being configured comparatively symmetrically thanks to the arrangement of the DC connections. This results in a comparatively even load on the individual alternating voltage phases during operation of the substrate or of the corresponding power module, which is particularly advantageous. This is because, during operation of the substrate or the power module of the present embodiments, unevenly loaded alternating voltage phases cause particularly strong heating of one of the alternating voltage phases. This impairs the service life of the components of this alternating voltage phase and thus the service life of the substrate and the power module. Further, it may be necessary to counter the explained strong heating of one of the alternating voltage phases structurally by additional cooling effort (e.g., relatively large heat sinks and the like), which causes higher costs and sometimes requires more installation space. This therefore results in a spatially larger power module without this achieving a greater electrical power.

Further, the configuration of the substrate of the present embodiments enables proven housing types to be used as the module housing. In addition, the explained arrangement of the DC connections, for example, permits capacitors to be positioned close to the relevant potential in each case (e.g., closer than 20% or 10% of the diagonal of the substrate in a plan view of the substrate). As a result, no new module types or housing types that are either larger or require new manufacturing technologies, for example, are needed. Further, it is thus easier to realize platforms in the device series.

In an embodiment, the three AC connections are arranged on one of the two long sides (e.g., on the first long side).

This provides that all three AC connections are arranged on one and the same long side, which facilitates a symmetrical design of the arrangement in particular. The three AC connections may be arranged, for example, on the first long side (e.g., in the above example for illustration, at the top) or on the second long side (e.g., in the above example for illustration, at the bottom), where the DC connections may be arranged as already explained above for symmetry reasons, or may be arranged symmetrically with respect to the middle of the substrate (e.g., in the above example for illustration, as follows: the positive DC connection is arranged at the top left, the first middle DC connection is arranged at the bottom left, the second middle DC connection is arranged at the top right, and the negative DC connection is arranged at the bottom right; or, for a mirrored arrangement, as follows: the negative DC connection is arranged at the top left, the second middle DC connection is arranged at the bottom left, the first middle DC connection is arranged at the top right, and the positive DC connection is arranged at the bottom right).

In another embodiment, the substrate is configured such that the impedances between the DC connections of two of the direct voltages for the three phases of the alternating voltage are equal within a tolerable deviation, the tolerable deviation being 25%, 15%, or 10%.

For example, therefore, the impedance (e.g., the alternating current resistance) between the positive DC connection and the negative DC connection is equal for the three phases of the alternating voltage within the tolerable deviation. This provides, for example, that the impedance between the positive DC connection and the negative DC connection along the first phase of the three-phase alternating voltage within the tolerable deviation is equal to the impedance between the positive DC connection and the negative DC connection along the second phase of the three-phase alternating voltage, both being equal within the tolerable deviation with the impedance between the positive DC connection and the negative DC connection along the third phase of the three-phase alternating voltage. The same applies for the impedances between the positive DC connection and the two DC connections of the medium/neutral direct voltage and for the impedances between the negative DC connection and the two DC connections of the medium/neutral direct voltage. The impedances are, for example, equal within the tolerable deviation (e.g., at the operating frequency of the substrate and/or of the semiconductors). If the semiconductors are configured as transistors, the impedances are equal within the tolerable deviation, for example, at the switching frequency and/or the clock frequency of the transistors. In some examples, the corresponding inductance may be equal within the tolerable deviation between the DC connections of two of the direct voltages for the three phases of the alternating voltage. Further details regarding this aspect are explained below in connection with FIG. 2.

The tolerable deviation is in the range of up to 25%, up to 15%, or up to 10%.

In order to design the impedances to be equal within the tolerable deviation, the substrate may be configured symmetrically or approximately symmetrically, for example. The symmetrical design of the substrate may include, for example, the three AC connections being arranged approximately equidistantly from one another and approximately in the middle between the two short sides. In one embodiment, the three AC connections are arranged very close to one another (e.g., closer than 20% or 10% of the diagonal of the substrate in a plan view of the substrate). Further, the electrical conductors and/or conductor paths that connect the AC connections to the semiconductors or the semiconductors to the DC connections may be configured approximately symmetrically and/or approximately with equal cross-sections and approximately with equal inductances. For example, the impedances of the electrical conductors and/or conductor paths are calculated or simulated in advance and are adjusted or coordinated with respect to one another such that the desired impedances are achieved. The adjustment or coordination may be achieved, for example, by the conductors or conductor paths being configured with a larger or smaller cross-section than originally planned or otherwise planned, or being guided on the substrate in a manner other than the shortest possible connection in order to coordinate the inductance or impedance of the conductors or conductor paths with respect to one another as optimally as possible.

In another embodiment, the substrate is configured such that the impedances between the positive DC connection and the two middle DC connections for the three phases of the alternating voltage are equal within the tolerable deviation and are also equal to the impedances between the negative DC connection and the two middle DC connections for the three phases of the alternating voltage within the tolerable deviation.

As mentioned above, the impedances between the positive DC connection and the two DC connections of the medium/neutral direct voltage are also equal to one another within the tolerable deviation, where the impedances between the negative DC connection and the two DC connections of the medium/neutral direct voltage are also equal to one another within the tolerable deviation. For reasons of symmetry and, for example, to achieve as even a load as possible of the individual alternating voltage phases during operation of the substrate and/or the power module, the impedances between the positive DC connection and the two DC connections of the medium/neutral direct voltage are equal, within the tolerable deviation, to the impedances between the negative DC connection and the two DC connections of the medium/neutral direct voltage, with the three phases of the alternating voltage being taken into account in each case. Further details regarding this aspect are explained below in connection with FIG. 2.

As already mentioned above, the power module of the present embodiments has a module housing that, for example, is configured partially as a frame and accommodates and fixes the substrate at its center. In addition to a frame-shaped housing part, the module housing may also have a cover that may serve, for example, to protect the substrate from environmental influences and to prevent hazards due to the voltages occurring during operation of the power module. In some examples, the module housing has a plurality of recesses for receiving connection pins. The three AC connections and the four DC connections of the substrate may then each be electrically connected to at least one connection pin, with the respective connection pin being housed in one of the recesses of the module housing.

In another embodiment, the power module has three module AC connections arranged on the long sides, which module AC connections are electrically connected to the three AC connections of the substrate, and four module DC connections arranged on the short sides, which module DC connections are electrically connected to the four DC connections of the substrate. The respective electrical connection may be established, for example, using the above-mentioned connection pins if the module housing has the connection pins.

In order that the power module may be supplied with the three-phase alternating voltage or the three direct voltages, and/or in order that the three-phase alternating voltage or the three direct voltages may be tapped at the power module, the power module has three module AC connections and four module DC connections. The three AC connections of the substrate are, for example, electrically connected to the three module AC connections, and the four DC connections of the substrate are electrically connected to the four module DC connections. As with the three AC connections of the substrate, the three module AC connections are arranged on the long sides, with the four module DC connections, as with the DC connections of the substrate, being arranged on the short sides. This design of the power module facilitates a short and direct electrical connection of the module AC connections or the module DC connections with the corresponding AC connections or DC connections of the substrate, with the electrical connection being established by the appropriate connection pins in some examples.

In another embodiment, the module DC connection electrically connected to the positive DC connection and the module DC connection electrically connected to the first middle DC connection are arranged on the first short side. The module DC connection electrically connected to the positive DC connection is arranged closer to the first long side than the module DC connection electrically connected to the first middle DC connection. The module DC connection electrically connected to the negative DC connection and the module DC connection electrically connected to the second middle DC connection are arranged on the second short side. The module DC connection electrically connected to the negative DC connection is arranged closer to the second long side than the module DC connection electrically connected to the second middle DC connection.

The explained embodiment and, for example, the explained arrangement of the module AC connections and of the module DC connections, facilitate a particularly short and direct electrical connection with the corresponding AC connections or DC connections, respectively, of the substrate. As a result, the electrical losses that occur during operation may be further reduced, as may unwanted inductances, with the above-mentioned even load of the individual alternating voltage phases being supported at the same time.

Specific embodiments of this aspect are explained below in connection with FIGS. 4 to 7.

In another embodiment, the power module further has a first backup capacitor that is connected between the positive direct voltage at the positive DC connection and the medium direct voltage at the first middle DC connection, and a second backup capacitor that is connected between the negative direct voltage at the negative DC connection and the medium direct voltage at the second middle DC connection.

In one embodiment, a backup capacitor or decoupling capacitor may be the use of a capacitor to stabilize the supply voltage in high-frequency and complex digital circuits. The backup capacitor has a similar function to a smoothing capacitor. For each circuit or circuit section, one or more capacitors are connected in parallel with the supply voltage that act as a voltage or energy source at times of high current or power demand. Through their low impedance at high frequencies, the capacitors reduce the impedance of the higher-level voltage supply or its supply line and prevent a mutual influence by the energy supply of partial circuits. On the output signal lines, the capacitors reduce both overshoot and undershoot of the signal level and thus the possibility of faults in signal processing. Conversely, capacitors may absorb disruptive, temporary overvoltages in electronic circuits and thus reduce their spread and damaging impact.

The explained (e.g., symmetrical) arrangement of the DC connections or module DC connections facilitates, for example, good positioning of backup capacitors for the relevant commutation branches outside the module. For example, the respective backup capacitor may be arranged very close (e.g., closer than 20% or 10% of the diagonal of the substrate in a plan view of the substrate) to the DC connections, by which electrical losses that occur during operation as well as unwanted inductances may be further reduced. In one embodiment, the electrical connection of the respective backup capacitor with the respective DC connection has a length of no more than 20% or 10% of the diagonal of the substrate in a plan view of the substrate.

In another embodiment, the power module further has a circuit board. The first backup capacitor and the second backup capacitor are each arranged on the circuit board.

The circuit board may, for example, be configured as a printed circuit board (PCB) or as a further DCB substrate or a further AMB substrate or the like. In one embodiment, the circuit board is arranged close to the substrate in order to guarantee short electrical connections of the respective backup capacitor with the respective DC connection.

In another embodiment, the first backup capacitor and the second backup capacitor are each arranged on the substrate.

Particularly short electrical connections of the respective backup capacitor with the respective DC connection may be achieved, for example, by the respective backup capacitor being arranged on the substrate and suitably electrically connected to the respective DC connection. In one embodiment, the first backup capacitor is arranged in the region of the first short side, and the second backup capacitor is arranged in the region of the second short side. The distance of the respective backup capacitor from the respective short side is, for example, no more than 20% or 10% of the diagonal of the substrate in a plan view of the substrate.

In another embodiment, the power module is able to be operated with an electrical power of at least several 10 kW (e.g., 40 kW to 500 kW), with an alternating voltage of at least several 100 V (e.g., 280 V to 800 V), with a direct voltage of at least several 100 V (e.g., 800 V to 1500 V), and/or electrical currents of several 10 A (e.g., 70 A to 1000 A).

As already mentioned above, the electrical device of the present embodiments has at least one power module, at least a first intermediate circuit capacitor, and at least a second intermediate circuit capacitor.

In some modified examples, the electrical device may be configured as a rectifier for rectifying a three-phase alternating voltage into the three direct voltages, for which the electrical device merely has, for example, a suitably electrically connected power module. In other modified examples, the electrical device may be configured as an inverter for inverting the three direct voltages into a three-phase alternating voltage, for which the electrical device merely has, for example, a suitably electrically connected power module. If the electrical device has both a rectifier and an inverter, the electrical device may be configured as a converter for converting a three-phase alternating voltage into another three-phase alternating voltage.

A particular advantage of the method of the present embodiments is that commercially available output power modules may be used, or at least their output module housing, which are available at low cost and in high quantities. For example, the IGBT modules “EconoDual 3” from Infineon Technologies AG, Munich, “SEMiX” from SEM IKRON Elektronik GmbH & Co. KG, Nuremberg, or “SD 3” from Siemens AG, Munich and/or their module housings may serve as output power module and/or output module housing. These IGBT modules are used specially for applications in 2-level technology (e.g., in order to realize a single half-bridge from multiple individual IGBT semiconductors).

According to the method of the present embodiments, for example, no expensive special adaptations are required, which sometimes have limited availability on the market due to the relatively low expected quantities. For example, for the output power module and/or the output module housing, a conventional circuit board and/or a conventional substrate may be dispensed with, because the output power module and/or the output module housing is equipped with the substrate of the present embodiments and is thus strengthened.

To this end, the output power module and/or output module housing explained above is equipped with the proposed substrate. The four DC connections of the substrate are then suitably electrically connected to the four output power module voltage connections.

In another embodiment, the positive DC connection and the first middle DC connection are electrically connected to the two output power module voltage connections arranged on the first short side, the output power module voltage connection electrically connected to the positive DC connection is arranged closer to the first long side than the output power module voltage connection electrically connected to the first middle DC connection, the negative DC connection and the second middle DC connection are electrically connected to the two output power module voltage connections arranged on the second short side, and the output power module voltage connection electrically connected to the negative DC connection is arranged closer to the second long side than the output power module voltage connection electrically connected to the second middle DC connection.

In one embodiment, the respective one of the four output power module voltage connections and the respective one of the four DC connections of the substrate are arranged on one and the same short side, enabling short electrical connections to be achieved between the suitable connections. The respective electrical connection may be shorter than 20% or 10% of the diagonal of the substrate in a plan view of the substrate.

In another embodiment, three module AC connections arranged on the long sides of the output power module are provided, and a respective electrical connection is established from the three AC connections of the substrate to the three module AC connections. In one embodiment, the three module AC connections and the three AC connections of the substrate are arranged on one and the same long side, enabling short electrical connections to be achieved between the suitable connections. The respective electrical connection may be shorter than 20% or 10% of the diagonal of the substrate in a plan view of the substrate.

### BRIEF DESCRIPTION OF THE DRAWINGS

FIG. 1 is a first example embodiment of a substrate;

FIG. 2 is a circuit diagram of a second example embodiment of the substrate;

FIGS. 3-8 are first to sixth example embodiments of a power module, respectively;

FIG. 9 is an example embodiment of the electrical device; and

FIG. 10 is a flow chart of an example embodiment of a method for producing an example embodiment of a power module.

### DETAILED DESCRIPTION

In the example embodiments, in each case, the arrangement of the AC connections AC1, AC2, AC3, and the DC connections DCP, DCM1, DCM2, DCN is configured such that a comparatively even distribution of the inductances among the three alternating voltage phases in the substrate 1 takes place and the comparatively even distribution of the impedances is also achieved by the impedances of the individual alternating voltage phases being configured comparatively symmetrically thanks to the arrangement of the DC connections DCP, DCM1, DCM2, DCN.

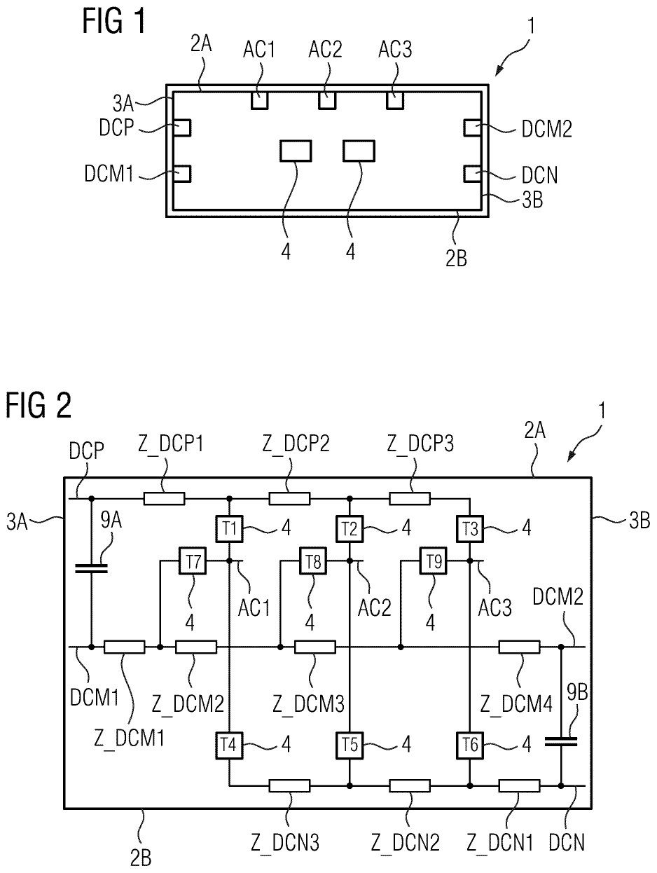

FIG. 1 shows a first example embodiment of the substrate 1 in a schematic plan view.

In the plan view shown, the substrate 1 is substantially rectangular and therefore has two opposing long sides 2A and 2B, and two opposing short sides 3A, 3B. Further, the substrate 1 has a plurality of semiconductors 4, where only two semiconductors 4 are shown in FIG. 1 for the sake of clarity. The semiconductors 4 serve to convert a three-phase alternating voltage (AC) into a positive, a medium, and a negative direct voltage (DC) or to convert a positive, a medium, and a negative direct voltage (DC) into a three-phase alternating voltage (AC).

On the long sides 2A, 2B, the substrate 1 has three AC connections AC1, AC2, AC3 for applying the three-phase alternating voltage (AC) to the substrate 1 or for tapping the three-phase alternating voltage (AC) from the substrate 1. The three AC connections AC1, AC2, AC3 may be arranged on one of the two long sides 2A, 2B (e.g., on the first long side 2A as shown in FIG. 1). On the first short side 3A, the substrate 1 has a positive DC connection DCP for applying a positive direct voltage to the substrate 1 or tapping the positive direct voltage from the substrate 1. Further, the substrate 1 has, on the first short side 3A, a first middle DC connection DCM1 for applying a medium or neutral direct voltage to the substrate 1 or tapping the medium or neutral direct voltage from the substrate 1. The positive DC connection DCP is arranged closer to the first long side 2A than the first middle DC connection DCM1.

On the second short side 3B, the substrate 1 has a negative DC connection DCN for applying a negative direct voltage to the substrate 1 or tapping the negative direct voltage from the substrate 1. Further, the substrate 1 has, on the second short side 3B, a second middle DC connection DCM2 for applying the medium or neutral direct voltage to the substrate 1 or tapping the medium or neutral direct voltage from the substrate 1. The negative DC connection DCN is arranged closer to the second long side 2B than the second middle DC connection DCM2.

For the voltage conversion, the semiconductors 4 are suitably interconnected and are electrically connected to the AC connections AC1, AC2, AC3 and the DC connections DCP, DCM1, DCM2, DCP, which is not shown in any more detail in FIG. 1 for the sake of clarity, but is shown by way of example in FIG. 2.

FIG. 2 shows a circuit diagram of a second example embodiment of the substrate 1, where the same reference signs as in FIG. 1 denote the same items.

In contrast with the first example embodiment, the substrate 1 according to the second example embodiment has a first backup capacitor 9A and a second backup capacitor 9B. The first backup capacitor 9A is connected between the positive direct voltage at the positive DC connection DCP and the medium direct voltage at the first middle DC connection DCM1. The second backup capacitor 9B is connected between the negative direct voltage at the negative DC connection DCN and the medium direct voltage at the second middle DC connection DCM2.

Alternatively, the first backup capacitor 9A and the second backup capacitor 9B may also be arranged outside the substrate 1 in the power module 5 (e.g., on a circuit board 10 that is encompassed by the power module).

The substrate 1 has a total of nine semiconductors 4 that are numbered consecutively with T1, T2 . . . , T9. Between the respective AC connection AC1, AC2 or AC3, one semiconductor 4 is arranged in each case to the positive DC connection DCP, to the two middle DC connections DCM1 and DCM2, and to the negative DC connection DCN. This arrangement permits the above-mentioned voltage conversion.

The substrate 1 further has a total of ten impedances Z. The notation Z DCXY is used for this in FIG. 2. X stands for the direct voltage potential (e.g., positive, medium/neutral, or negative direct voltage DCP, DCM, DCN), and Y is consecutively numbered for every direct voltage potential.

In one embodiment, the substrate 1 is configured such that the impedances Z between the DC connections DCP, DCM1, DCM2, DCN of two of the direct voltages for the three phases of the alternating voltage are equal within a tolerable deviation. The tolerable deviation is, for example, 25%, 15%, or 10%.

In this example, therefore, the impedances between the positive DC connection DCP and the negative DC connection DCN are equal for the three phases of the alternating voltage within the tolerable deviation. In other words, therefore, due to series connection of the individual impedances:
For the first alternating voltage phase (connected to the AC connection AC1):

$$Z ( DCP -> DCN , AC 1 ) = Z\_DCP1 + Z\_DCN3 + Z\_DCN2 + Z\_DCN1$$

For the second alternating voltage phase (connected to the AC connection AC2): Z(DCP->DCN, AC2)=Z_DCP1+Z_DCP2+Z_DCN2+Z_DCN1
For the third alternating voltage phase (connected to the AC connection AC3): Z(DCP->DCN, AC3)=Z_DCP1+Z_DCP2+Z_DCP3+Z_DCN1, where Z(DCP->DCN, AC1), Z(DCP->DCN, AC2), and Z(DCP->DCN, AC3) should be equal within the tolerable deviation.

Further, in this example, the impedances between the positive DC connection DCP and the negative DC connection DCN and the two middle DC connections DCM1 and DCM2 are equal for the three phases of the alternating voltage within the tolerable deviation. In other words, therefore, due to a partial series connection and partial parallel connection of the individual impedances (noted with “∥”, where the reciprocal of a total impedance for parallel connection of individual impedances results from the sum of the reciprocals of the individual impedances)):
For the first alternating voltage phase (connected to the AC connection AC1):

$$Z ( DCP -> DCM 1 / DCM 2 , AC 1 ) = Z\_DCP1 + ( Z\_DCM1 ‖ ( Z\_DCM2 + Z\_DCM3 + Z\_DCM4 ) )$$

$$Z ( DCN -> DCM 1 / DCM 2 , AC 1 ) = Z\_DCN1 + Z\_DCN2 + Z\_DCN3 + ( Z DCM 1 ‖ ( Z\_DCM2 + Z\_DCM3 + Z\_DCM4 ) )$$

For the second alternating voltage phase (connected to the AC connection AC2):

$$Z ( DCP -> DCM 1 / DCM 2 , AC 2 ) = Z\_DCP1 + Z\_DCP2 + ( ( Z\_DCM2 + Z\_DCM1 ) ‖ ( Z\_DCM3 + Z\_DCM4 ) ) Z ( DCN -> DCM 1 / DCM 2 , AC 2 ) = Z\_DCN1 + Z\_DCN2 + ( Z\_DCM 2 + Z DCM 1 ) ‖ ( Z\_DCM3 + Z\_DCM4 ) )$$

For the third alternating voltage phase (connected to the AC connection AC3):

$$Z ( DCP -> DCM 1 / DCM 2 , AC 3 ) = Z\_DCP1 + Z\_DCP2 + Z\_DCP3 + ( ( Z\_DCM3 + Z\_DCM2 + Z\_DCM1 ) ‖ Z\_DCM4 )$$

$$Z ( DCN -> DCM 1 / DCM 2 , AC 3 ) = Z\_DCN1 + ( ( Z\_DCN3 + Z\_DCN2 + Z\_DCN1 ) ‖ Z\_DCM4 )$$

where Z(DCP->DCM1/DCM2, AC1), Z(DCP->DCM1/DCM2, AC2), and Z(DCP->DCM1/DCM2, AC3) should be equal within the tolerable deviation, where Z(DCN->DCM1/DCM2, AC1), Z(DCN->DCM1/DCM2, AC2), and Z(DCN->DCM1/DCM2, AC3) should also be equal within the tolerable deviation, and finally, for reasons of symmetry, Z(DCP->DCM1/DCM2, AC1), Z(DCP->DCM1/DCM2, AC2), and Z(DCP->DCM1/DCM2, AC3) as well as Z(DCN->DCM1/DCM2, AC1), Z(DCN->DCM1/DCM2, AC2), and Z(DCN->DCM1/DCM2, AC3) should also be equal within the tolerable deviation.

If the semiconductors 4 are configured as transistors T1, T2, . . . , T9, the impedances Z are equal within the tolerable deviation, for example, at the switching frequency and/or the clock frequency of the transistors T1, T2, . . . , T9. In some examples, the corresponding inductance may be equal within the tolerable deviation between the DC connections of two of the direct voltages for the three phases of the alternating voltage.

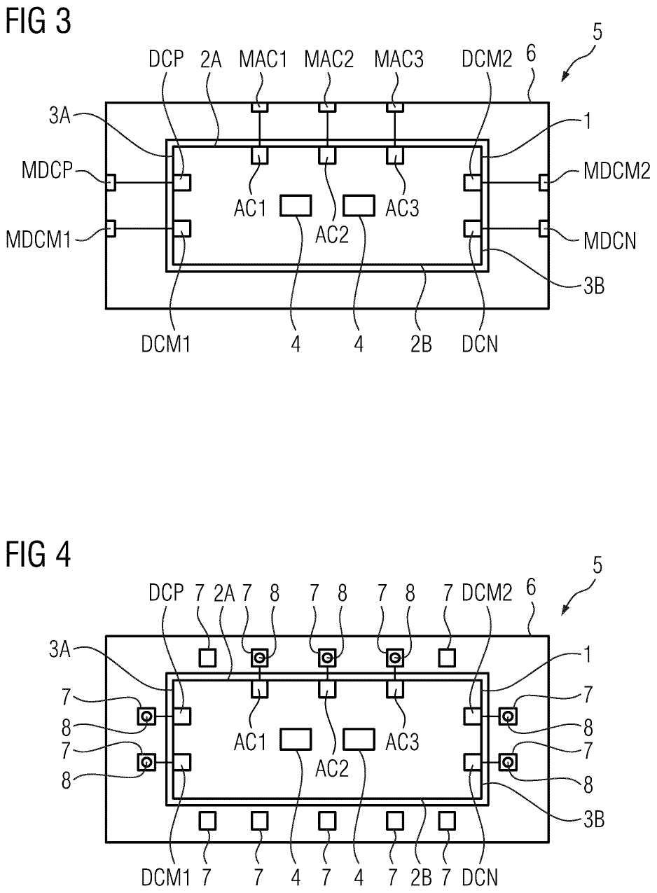

FIG. 3 shows a first example embodiment of the power module 5 in a schematic plan view.

The power module 5 has a substrate 1 that has similarities with the substrate 1 according to the first example embodiment. Further, the power module 5 has a module housing 6 that partially encloses the substrate 1. Further, the power module 5 has three module AC connections MAC1, MAC2, MAC3 arranged on the long sides 2A, 2B that are electrically connected to the three AC connections AC1, AC2, AC3 of the substrate 1. The three module AC connections MAC1, MAC2, MAC3 may be arranged on one of the two long sides 2A, 2B (e.g., on the first long side 2A as shown in FIG. 1). Further, the power module has four module DC connections MDCP, MDCM1, MDCM2, MDCN arranged on the short sides 3A, 3B that are electrically connected to the four DC connections DCP, DCM1, DCM2, DCN of the substrate 1.

FIG. 4 shows a second example embodiment of the power module 5 in a schematic plan view.

The power module 5 has a substrate 1 that has similarities with the substrate 1 according to the first example embodiment. Further, the power module 5 has a module housing 6 that partially encloses the substrate 1. The module housing 6 has a plurality of recesses 7, with one connection pin 8 in each case being accommodated in some of the recesses 7. In one embodiment, one connection pin 8 in each case is accommodated in those recesses 7 that are arranged close to the DC connections DCP, DCM1, DCM2, DCN or the AC connections AC1, AC2, AC3 of the substrate 1. Three of the connection pins 8 are electrically connected to the three AC connections AC1, AC2, AC3 of the substrate 1, and four of the connection pins 8 are electrically connected to the four DC connections DCP, DCM1, DCM2, DCN of the substrate 1.

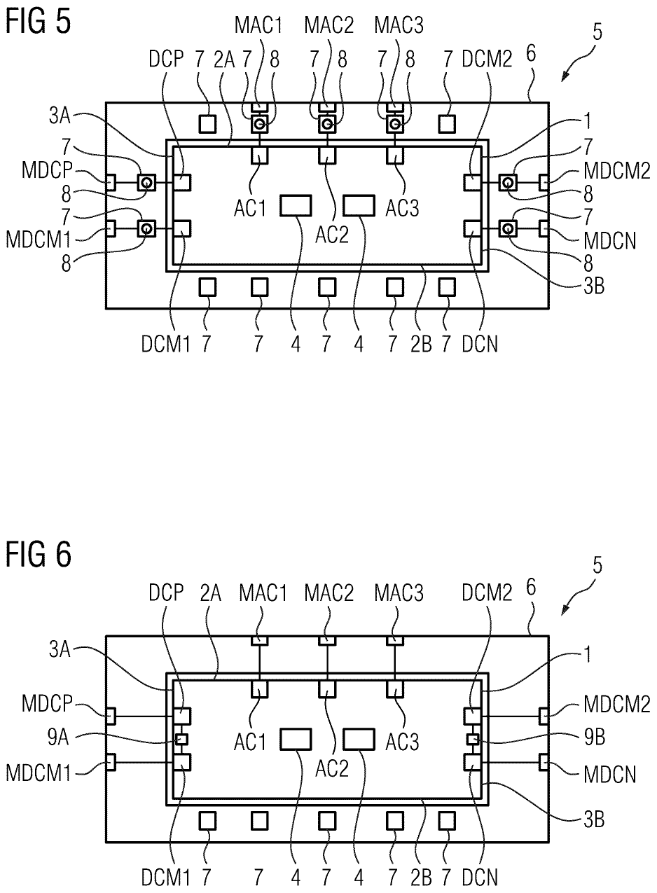

FIG. 5 shows a third example embodiment of the power module 5, again in a schematic plan view.

The power module 5 has similarities with the power module 5 according to the second example embodiment. Further, the power module 5 has three module AC connections MAC1, MAC2, MAC3 arranged on the long sides 2A, 2B that are electrically connected to the three AC connections AC1, AC2, AC3 of the substrate 1 via the three above-mentioned connection pins 8. The three module AC connections MAC1, MAC2, MAC3 may be arranged on one of the two long sides 2A, 2B (e.g., on the first long side 2A as shown in FIG. 1). Further, the power module has four module DC connections MDCP, MDCM1, MDCM2, MDCN arranged on the short sides 3A, 3B, which are electrically connected to the four DC connections DCP, DCM1, DCM2, DCN of the substrate 1 via the four above-mentioned connection pins 8.

As shown in FIG. 5, the module DC connection MDCP electrically connected to the positive DC connection DCP and the module DC connection MDCM1 electrically connected to the first middle DC connection DCM1 are arranged on the first short 3A side. The module DC connection MDCP electrically connected to the positive DC connection DCP is arranged closer to the first long side 2A than the module DC connection MDCM1 electrically connected to the first middle DC connection DCM1. Further, the module DC connection MDCN electrically connected to the negative DC connection DCN and the module DC connection MDCM2 electrically connected to the second middle DC connection DCM2 are arranged on the second short side 3B. The module DC connection MDCN electrically connected to the negative DC connection DCN is arranged closer to the second long side 2B than the module DC connection MDCM2 electrically connected to the second middle DC connection DCM2.

FIG. 6 shows a fourth example embodiment of the power module 5, again in a schematic plan view.

The power module 5 has similarities with the power module 5 according to the first example embodiment. Further, the power module 5 has a first backup capacitor 9A and a second backup capacitor 9B that are both arranged on the substrate 1. The first backup capacitor 9A is connected between the positive direct voltage at the positive DC connection DCP and the medium direct voltage at the first middle DC connection DCM1. The second backup capacitor 9B is connected between the negative direct voltage at the negative DC connection DCN and the medium direct voltage at the second middle DC connection DCM2.

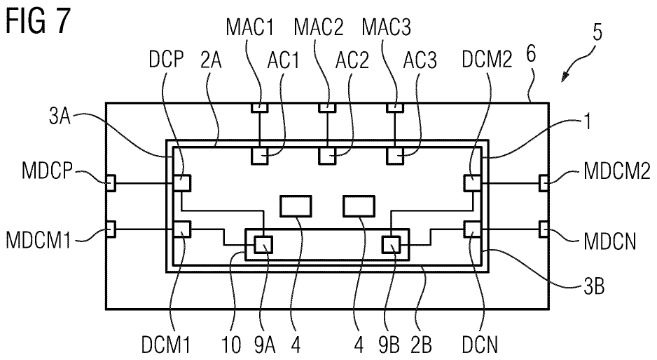

FIG. 7 shows a fifth example embodiment of the power module 5, again in a schematic plan view.

The power module 5 has similarities with the power module 5 according to the fourth example embodiment, with the arrangement of the first backup capacitor 9A and the second backup capacitor 9B differing from the fourth example embodiment. The power module 5 has, for example, a circuit board 10 on which the first backup capacitor 9A and the second backup capacitor 9B are arranged. The first backup capacitor 9A and the second backup capacitor 9B are again suitably electrically connected to the DC connections DCP, DCM1, DCM2, DCN as explained above.

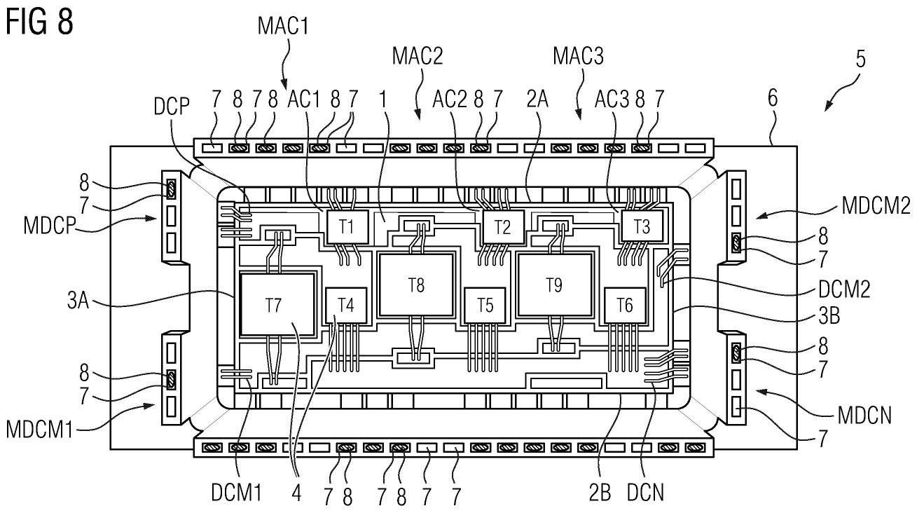

FIG. 8 shows a sixth example embodiment of the power module 5, where a relatively realistic representation is shown in a schematic plan view.

The power module 5 has major similarities with the power module 5 according to the third example embodiment.

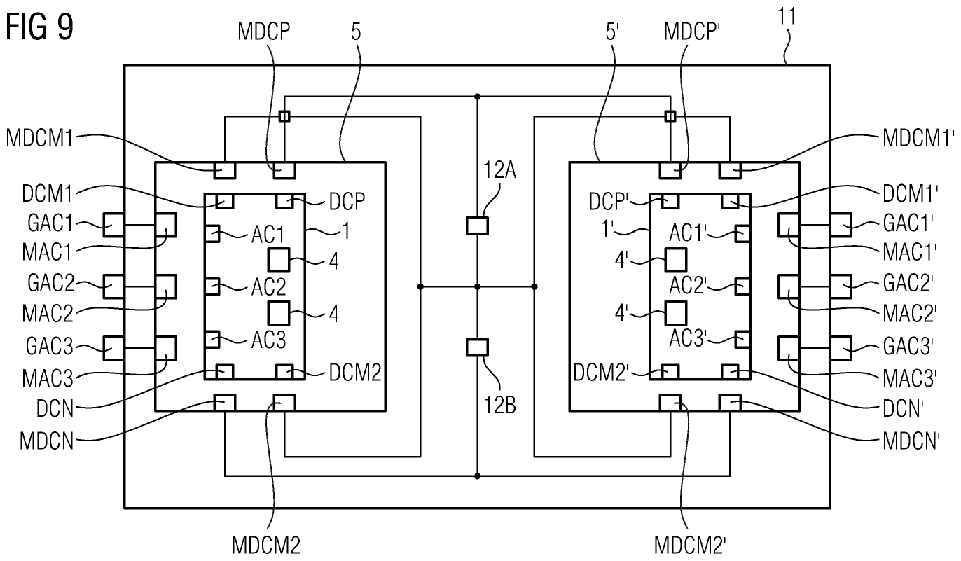

FIG. 9 shows an example embodiment of the electrical device 11 in a schematic plan view.

The electrical device 11 shown is a converter that may convert a three-phase alternating voltage that may be fed in via the device AC connections GAC1, GAC2, GAC3 into another three-phase alternating voltage that may be tapped via the device AC connections GAC1′, GAC2′, GAC3′. The electrical device 11 has two power modules 5 and 5′, each of which may be configured as a power module according to the second example embodiment explained above, for example. For reasons of clarity, some details of the two power modules 5 and 5′ are merely indicated in FIG. 9 and are not represented more precisely.

The device AC connections GAC1, GAC2, GAC3 are electrically connected to the module AC connections MAC1, MAC2, MAC3 of the first power module 5, and the device AC connections GAC1′, GAC2′, GAC3′ are electrically connected to the module AC connections MAC1′, MAC2′, MAC3′ of the second power module 5′.

The electrical device 11 further has a first intermediate circuit capacitor 12A that is connected to the module DC connections MDCP, MDCP′ for the positive direct voltage of the two power modules 5 and 5′. The first intermediate circuit capacitor 12A is connected to the module DC connections MDCM1, MDCM2, MDCM1′, MDCM2′ for the medium/neutral direct voltage of the two power modules 5 and 5′.

In addition, the electrical device 11 has a second intermediate circuit capacitor 12B that is connected to the module DC connections MDCN, MDCN′ for the negative direct voltage of the two power modules 5 and 5′. The second intermediate circuit capacitor 12B is connected to the module DC connections MDCM1, MDCM2, MDCM1′, MDCM2′ for the medium/neutral direct voltage of the two power modules 5 and 5′.

In some modified examples, the electrical device 11 may also be configured as a rectifier for rectifying a three-phase alternating voltage into the three direct voltages, for which the second power module 5′ (e.g., in FIG. 9, on the right) and the device AC connections GAC1′, GAC2′, GAC3′ are dispensed with. In other modified examples, the electrical device 11 may also be configured as an inverter for inverting the three direct voltages into a three-phase alternating voltage, for which the first power module 5′ (e.g., in FIG. 9, on the left) and the device AC connections GAC1, GAC2, GAC3 are dispensed with.

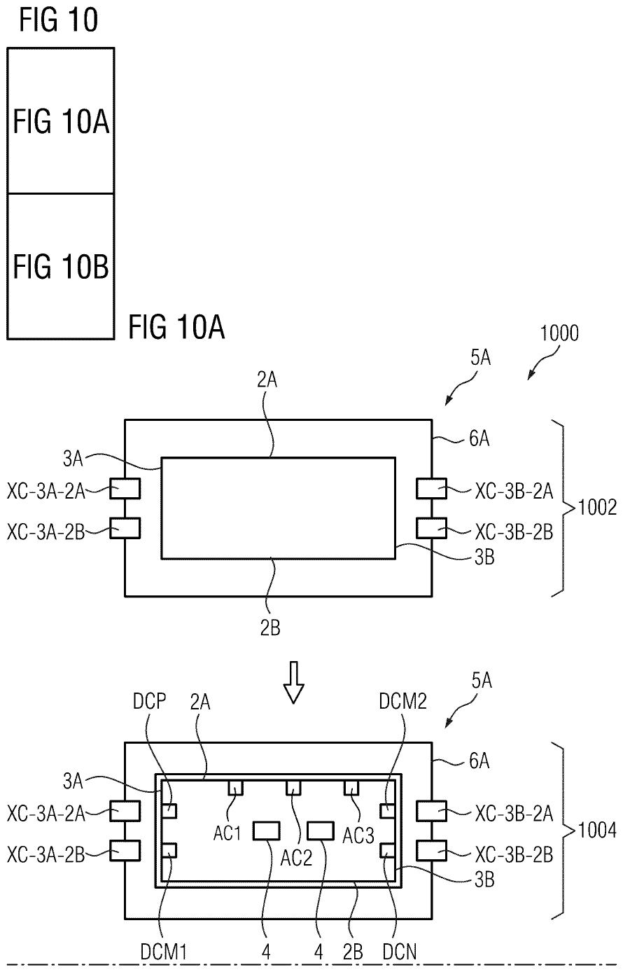

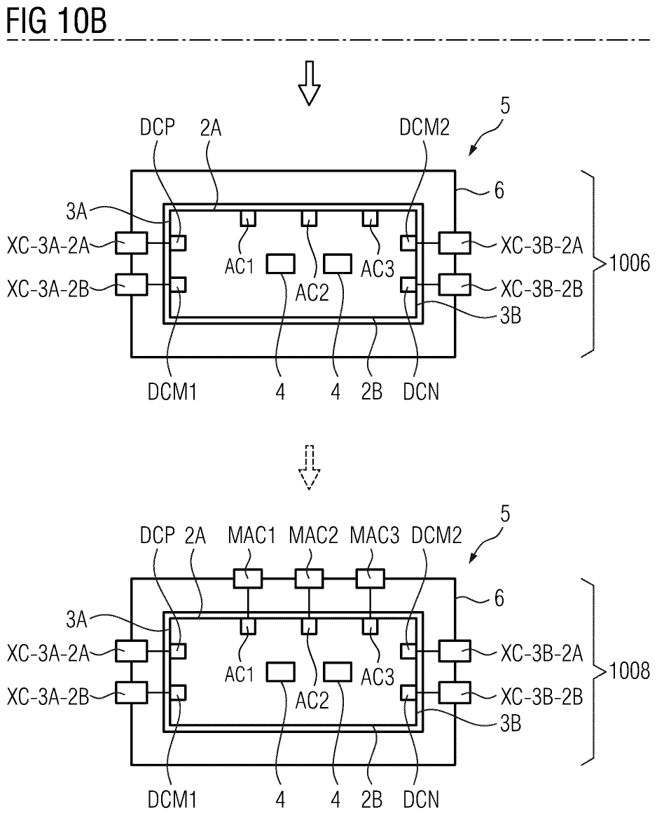

FIG. 10 shows an example embodiment of a method 1000 for producing an example embodiment of a power module 5. The method includes the following method acts.

In a method act 1002, an output power module 5A that has two output power module voltage connections XC-3A-2A, XC-3A-2B arranged on the first short side 3A is provided. Further, the output power module 5A has two output power module voltage connections XC-3B-2A, XC-3B-2B arranged on the second short side 3B. Further, the output power module 5A has an output module housing 6A for accommodating and for at least partially enclosing the substrate 1.

In a method act 1004, the substrate 1 is inserted into the output power module 5A.

In a method act 1006, a respective electrical connection from the four DC connections DCP, DCM1, DCM2, DCN of the substrate 1 to the four output power module voltage connections XC-3A-2A, XC-3A-2B, XC-3B-2A, XC-3B-2B is established.

In one embodiment, the positive DC connection DCP and the first middle DC connection DCM1 are electrically connected to the two output power module voltage connections XC-3A-2A, XC-3A-2B arranged on the first short side 3A. The output power module voltage connection XC-3A-2A electrically connected to the positive DC connection DCP is arranged closer to the first long side 2A than the output power module voltage connection XC-3A-2B electrically connected to the first middle DC connection DCM1. Further, the negative DC connection DCN and the second middle DC connection DCM2 are electrically connected to the two output power module voltage connections XC-3B-2A, XC-3B-2B arranged on the second short side 3B. The output power module voltage connection XC-3B-2B electrically connected to the negative DC connection DCN is arranged closer to the second long side 2B than the output power module voltage connection XC-3B-2A electrically connected to the second middle DC connection DCM2.

In an optional method act 1008 (indicated with the dashed arrow), three module AC connections MAC1, MAC2, MAC3 arranged on the long sides 2A, 2B of the output power module 5A are provided, and a respective electrical connection from three AC connections AC1, AC2, AC3 of the substrate 1 is established with the three module AC connections MAC1, MAC2, MAC3.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1.-15. (canceled)

16. A substrate for a power module, wherein the substrate is substantially rectangular in plan view with two opposing long sides and two opposing short sides, the substrate comprising:
a plurality of semiconductors for converting a three-phase alternating voltage into a positive, a medium, and a negative direct voltage or for converting a positive, a medium, and a negative direct voltage into a three-phase alternating voltage;
three alternating current (AC) connections arranged on the two opposing long sides;
a positive direct current (DC) connection located on a first short side of the two opposing short sides;
a first middle DC connection arranged on the first short side;
a second middle DC connection arranged on a second short side of the two opposing short sides; and
a negative DC connection arranged on the second short side,
wherein the positive DC connection is arranged closer to a first long side of the two opposing long sides than the first middle DC connection,
wherein the negative DC connection is arranged closer to a second long side of the two opposing long sides than the second middle DC connection, and
wherein an arrangement of the three AC connections, the positive DC connection, the first middle DC connection, the second middle DC connection, and the negative DC connection is configured such that a comparatively even distribution of inductances among the three alternating voltage phases in the substrate takes place and a comparatively even distribution of impedances is also achieved by impedances of the individual alternating voltage phases being configured comparatively symmetrically thanks to an arrangement of the positive DC connection, the first middle DC connection, the second middle DC connection, and the negative DC connection.

17. The substrate of claim 16, wherein the three AC connections are arranged on one of the two opposing long sides.

18. The substrate of claim 17, wherein the three AC connections are arranged on the first long side.

19. The substrate of claim 16, wherein the substrate is configured such that impedances between the positive DC connection, the first middle DC connection, the second middle DC connection, and the negative DC connection of two of the direct voltages for the three phases of the alternating voltage are equal within a tolerable deviation, and
wherein the tolerable deviation is 25%, 15%, or 10%.

20. The substrate of claim 19, wherein the substrate is configured such that the impedances between the positive DC connection and the first middle DC connection and the second middle DC connection for the three phases of the alternating voltage are equal within the tolerable deviation and are also equal to the impedances (Z) between the negative DC connection and the first middle DC connection and the second middle DC connection for the three phases of the alternating voltage within the tolerable deviation.

21. A power module comprising:
a substrate that is substantially rectangular in plan view with two opposing long sides and two opposing short sides, the substrate comprising:
a plurality of semiconductors for converting a three-phase alternating voltage into a positive, a medium, and a negative direct voltage or for converting a positive, a medium, and a negative direct voltage into a three-phase alternating voltage;
three alternating current (AC) connections arranged on the two opposing long sides;
a positive direct current (DC) connection located on a first short side of the two opposing short sides;
a first middle DC connection arranged on the first short side;
a second middle DC connection arranged on a second short side of the two opposing short sides; and
a negative DC connection arranged on the second short side, wherein the positive DC connection is arranged closer to a first long side of the two opposing long sides than the first middle DC connection, wherein the negative DC connection is arranged closer to a second long side of the two opposing long sides than the second middle DC connection, and wherein an arrangement of the three AC connections, the positive DC connection, the first middle DC connection, the second middle DC connection, and the negative DC connection is configured such that a comparatively even distribution of inductances among the three alternating voltage phases in the substrate takes place and a comparatively even distribution of impedances is also achieved by impedances of the individual alternating voltage phases being configured comparatively symmetrically thanks to an arrangement of the positive DC connection, the first middle DC connection, the second middle DC connection, and the negative DC connection; and
a module housing that at least partially encloses the substrate.

22. The power module of claim 21, further comprising:
three module AC connections arranged on the long sides, the three module AC connections being electrically connected to the three AC connections of the substrate; and
four module DC connections arranged on the short sides, the four module DC connections being electrically connected to the four DC connections of the substrate.

23. The power module of claim 22, wherein the module DC connection electrically connected to the positive DC connection and the module DC connection electrically connected to the first middle DC connection are arranged on the first short side,
wherein the module DC connection electrically connected to the positive DC connection is arranged closer to the first long side than the module DC connection electrically connected to the first middle DC connection,
wherein the module DC connection electrically connected to the negative DC connection and the module DC connection electrically connected to the second middle DC connection are arranged on the second short side, and
wherein the module DC connection electrically connected to the negative DC connection is arranged closer to the second long side than the module DC connection electrically connected to the second middle DC connection.

24. The power module of claim 21, further comprising:
a first backup capacitor that is connected between the positive direct voltage at the positive DC connection and the medium direct voltage at the first middle DC connection; and
a second backup capacitor that is connected between the negative direct voltage at the negative DC connection and the medium direct voltage at the second middle DC connection.

25. The power module of claim 24, further comprising a circuit board,
wherein the first backup capacitor and the second backup capacitor each are arranged on the circuit board.

26. The power module of claim 24, wherein the first backup capacitor and the second backup capacitor are each arranged on the substrate.

27. The power module of claim 21, wherein the power module is operable with an electrical power of 40 kW to 500 kW, with an alternating voltage of 280 V to 800 V, with a direct voltage of 800 V to 1500 V, with electrical currents of 70 A to 1000 A, or any combination thereof.

28. An electrical device comprising:
at least one power module, a power module of the at least one power module comprising:
a substrate that is substantially rectangular in plan view with two opposing long sides and two opposing short sides, the substrate comprising:
a plurality of semiconductors for converting a three-phase alternating voltage into a positive, a medium, and a negative direct voltage or for converting a positive, a medium, and a negative direct voltage into a three-phase alternating voltage;
three alternating current (AC) connections arranged on the two opposing long sides;
a positive direct current (DC) connection located on a first short side of the two opposing short sides;
a first middle DC connection arranged on the first short side;
a second middle DC connection arranged on a second short side of the two opposing short sides; and
a negative DC connection arranged on the second short side, wherein the positive DC connection is arranged closer to a first long side of the two opposing long sides than the first middle DC connection, wherein the negative DC connection is arranged closer to a second long side of the two opposing long sides than the second middle DC connection, and wherein an arrangement of the three AC connections, the positive DC connection, the first middle DC connection, the second middle DC connection, and the negative DC connection is configured such that a comparatively even distribution of inductances among the three alternating voltage phases in the substrate takes place and a comparatively even distribution of impedances is also achieved by impedances of the individual alternating voltage phases being configured comparatively symmetrically thanks to an arrangement of the positive DC connection, the first middle DC connection, the second middle DC connection, and the negative DC connection; and
a module housing that at least partially encloses the substrate
at least a first intermediate circuit capacitor that is connected between the module DC connection electrically connected to the positive DC connection and the module DC connections electrically connected to the middle DC connections; and
at least a second intermediate circuit capacitor that is connected between the module DC connection electrically connected to the negative DC connection and the module DC connections electrically connected to the middle DC connections.

29. The electrical device of claim 28, wherein the electrical device is a converter, and
wherein the at least one power module comprises at least two power modules.

30. A method for producing a power module, the power module comprising a substrate for a power module, wherein the substrate is substantially rectangular in plan view with two opposing long sides and two opposing short sides, the substrate comprising a plurality of semiconductors for converting a three-phase alternating voltage into a positive, a medium, and a negative direct voltage or for converting a positive, a medium, and a negative direct voltage into a three-phase alternating voltage, three alternating current (AC) connections arranged on the two opposing long sides, a positive direct current (DC) connection located on a first short side of the two opposing short sides, a first middle DC connection arranged on the first short side, a second middle DC connection arranged on a second short side of the two opposing short sides, and a negative DC connection arranged on the second short side, wherein the positive DC connection is arranged closer to a first long side of the two opposing long sides than the first middle DC connection, wherein the negative DC connection is arranged closer to a second long side of the two opposing long sides than the second middle DC connection, and wherein an arrangement of the three AC connections, the positive DC connection, the first middle DC connection, the second middle DC connection, and the negative DC connection is configured such that a comparatively even distribution of inductances among the three alternating voltage phases in the substrate takes place and a comparatively even distribution of impedances is also achieved by impedances of the individual alternating voltage phases being configured comparatively symmetrically thanks to an arrangement of the positive DC connection, the first middle DC connection, the second middle DC connection, and the negative DC connection, the power module further comprising a module housing that at least partially encloses the substrate, the method comprising:
providing an output power module having:
at least two output power module voltage connections arranged on the first short side;
at least two output power module voltage connections arranged on the second short side; and
an output module housing for accommodating and for at least partially enclosing the substrate;
inserting the substrate into the output power module; and
establishing a respective electrical connection from the positive DC connection, the first middle DC connection, the second middle DC connection, and the negative DC connection of the substrate to the at least two output power module voltage connections arranged on the first short side and the at least two output power module voltage connections arranged on the second short side.

31. The method of claim 30, wherein the positive DC connection and the first middle DC connection are electrically connected to the two output power module voltage connections arranged on the first short side,
wherein the output power module voltage connection electrically connected to the positive DC connection is arranged closer to the first long side than the output power module voltage connection electrically connected to the first middle DC connection,
wherein the negative DC connection and the second middle DC connection are electrically connected to the two output power module voltage connections arranged on the second short side, and
wherein the output power module voltage connection electrically connected to the negative DC connection is arranged closer to the second long side than the output power module voltage connection electrically connected to the second middle DC connection.

32. The method of claim 30, further comprising:
providing three module AC connections arranged on the long sides of the output power module; and
establishing a respective electrical connection from the three AC connections of the substrate to the three module AC connections.
